(19) United States
(12) Patent Application Publication
(10) Pub. No.: US 2026/0047191 A1
(43) Pub. Date: Feb. 12, 2026

(54) FETS WITH DUMMY NANOSHEETS

(71) Applicant: INTERNATIONAL BUSINESS MACHINES CORPORATION, Armonk, NY (US)

(72) Inventors: Xiaoming Yang, Clifton Park, NY (US); Ruilong Xie, Niskayuna, NY (US); Tao Li, Slingerlands, NY (US); Julien Frougier, Albany, NY (US)

(21) Appl. No.: 18/738,404

(22) Filed: Jun. 10, 2024

(51) Int. Cl. H10D 84/83; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/121; H10D 62/151; H10D 64/251; H10D 84/0149; H10D 84/8312; H10D 30/014; H10D 30/0191

(57) ABSTRACT

Semiconductor devices include stacked nanosheet channels with inner spacers between respective pairs of the stacked nanosheet channels. Dummy nanosheet remnants are below respective inner spacers, vertically aligned with the respective inner spacers. A source/drain structure is on sidewalls of the plurality of stacked nanosheet channels. A backside contact makes contact with the source/drain structure.

### BACKGROUND

The present invention generally relates to semiconductor device fabrication and, more particularly, to the fabrication of devices with backside contacts.

Field effect transistors (FETs) may be formed with self-aligned substrate isolation layers, which are dielectric layers that insulate the FETs from an underlying substrate. A placeholder structure may be formed underneath the source/drain structures of the FETs to facilitate later formation of contacts from the back side of the device. However, penetrating the self-aligned substrate isolation layer to form the placeholder structure can result in placeholder structures that risk shorting to adjacent nanosheets or other structures.

### SUMMARY

A semiconductor device includes stacked nanosheet channels with inner spacers between respective pairs of the stacked nanosheet channels. Dummy nanosheet remnants are below respective inner spacers, vertically aligned with the respective inner spacers. A source/drain structure is on sidewalls of the plurality of stacked nanosheet channels. A backside contact makes contact with the source/drain structure.

A semiconductor device includes stacked nanosheet channels with inner spacers between respective pairs of the stacked nanosheet channels. Dummy nanosheet remnants are below respective inner spacers, vertically aligned with the respective inner spacers. A first source/drain structure is on first sidewalls of the plurality of stacked nanosheet channels. A second source/drain structure is on second sidewalls of the plurality of stacked nanosheet channels. A backside contact makes contact with the first source/drain structure. A frontside contact makes contact with the second source/drain structure.

A semiconductor device includes stacked nanosheet channels with inner spacers between respective pairs of the stacked nanosheet channels. Dummy nanosheet remnants are below respective inner spacers, vertically aligned with the respective inner spacers. A first source/drain structure is on first sidewalls of the plurality of stacked nanosheet channels. A second source/drain structure is on second sidewalls of the plurality of stacked nanosheet channels. A gate stack is around the stacked nanosheet channels. A first backside interlayer dielectric of a first dielectric material directly contacts the dummy nanosheet remnants and the gate stack. A backside contact makes contact with the first source/drain structure, through the first backside interlayer dielectric. A frontside contact makes contact with the second source/drain structure.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a semiconductor device that indicates a set of cross-sectional planes that show different regions of the device, in accordance with an embodiment of the present invention;

FIG. 2 is cross-sectional view along multiple cross-sectional planes that illustrates a step in the fabrication of a semiconductor device where placeholder structures are formed underneath source/drain structures of a field effect transistor (FET), in accordance with an embodiment of the present invention;

FIG. 3 is cross-sectional view along multiple cross-sectional planes that illustrates a step in the fabrication of a semiconductor device where placeholder caps are formed underneath source/drain structures of a FET, in accordance with an embodiment of the present invention;

FIG. 4 is cross-sectional view along multiple cross-sectional planes that illustrates a step in the fabrication of a semiconductor device where the substrate is removed from the back side of the device, in accordance with an embodiment of the present invention;

FIG. 5 is cross-sectional view along multiple cross-sectional planes that illustrates a step in the fabrication of a semiconductor device where a dummy nanosheet is anisotropically etched away, in accordance with an embodiment of the present invention;

FIG. 6 is cross-sectional view along multiple cross-sectional planes that illustrates a step in the fabrication of a semiconductor device a backside interlayer dielectric is deposited, in accordance with an embodiment of the present invention;

FIG. 7 is cross-sectional view along multiple cross-sectional planes that illustrates a step in the fabrication of a semiconductor device where placeholder structures are replaced with backside contacts, through the backside interlayer dielectric, in accordance with an embodiment of the present invention;

FIG. 8 is cross-sectional view along multiple cross-sectional planes that illustrates a step in the fabrication of a semiconductor device a two-layer backside interlayer dielectric is deposited, in accordance with an embodiment of the present invention;

FIG. 9 is cross-sectional view along multiple cross-sectional planes that illustrates a step in the fabrication of a semiconductor device where placeholder structures are replaced with backside contacts, through the two-layer backside interlayer dielectric, in accordance with an embodiment of the present invention;

FIG. 10 is a block/flow diagram of a method of fabricating a semiconductor device, in accordance with an embodiment of the present invention.

### DETAILED DESCRIPTION

Nanosheet field effect transistors (FETs) may be formed with a process that starts with an extra nanosheet relative to the number of channel nanosheets in the final device. After the semiconductor substrate is removed during backside processing, the bottommost nanosheet may be removed and may be replaced by a backside interlayer dielectric before backside contacts are formed. The additional space between the lowest remaining nanosheet and the backside contact helps to prevent shorting.

According to an aspect of the invention, there is provided a semiconductor device includes stacked nanosheet channels with inner spacers between respective pairs of the stacked nanosheet channels. Dummy nanosheet remnants are below respective inner spacers, vertically aligned with the respective inner spacers. A source/drain structure is on sidewalls of the plurality of stacked nanosheet channels. A backside contact makes contact with the source/drain structure. The removal of the dummy nanosheet, which leaves the dummy nanosheet remnants behind, provides additional space between the channels of the device and the backside contact to prevent shorting.

In embodiments, a first backside interlayer dielectric of a first dielectric material directly contacts the dummy nanosheet remnants. This first backside interlayer dielectric provides electrical insulation between the channels of the device and the backside contact.

In embodiments, a second backside interlayer dielectric of a second dielectric material, distinct from the first dielectric material, is around the backside contact. The use of two distinct backside interlayer dielectric materials helps to provide etch selectivity during a pre-silicide cleaning process, which helps to prevent shorts between the backside contacts and a gate stack.

In embodiments, the first backside interlayer dielectric comprises silicon carbide or silicon oxycarbide and the second backside interlayer dielectric comprises silicon oxide. These materials are selectively etchable, to protect the backside contacts and gate stack during pre-silicide cleaning.

In embodiments, a gate stack is around the stacked nanosheet channels and in direct contact with the first backside interlayer dielectric. This gate stack provides an electrical field to trigger the channel during operation of the device.

In embodiments, there is a frontside contact to the gate stack. The use of both frontside and backside contacts to the device helps to simplify interconnect layout.

In embodiments, a semiconductor placeholder structure is in the first backside interlayer dielectric. This remaining semiconductor placeholder is formed to improve critical dimension and etch uniformity, and need not be removed in the finished device.

In embodiments, a placeholder cap of a third dielectric material, distinct from the first dielectric material, is on the semiconductor placeholder structure. The placeholder cap may be left over from fabrication of the device, with remnant placeholders improving critical dimension and etch uniformity.

In embodiments, the dummy nanosheet remnants are formed from a same semiconductor material as the plurality of stacked nanosheet channels. The dummy nanosheet remnants may be formed by creating an extra dummy nanosheet and subsequently etching it away from the back side of the device, leaving the dummy nanosheet remnants behind.

In embodiments, the dummy nanosheet remnants have a same width as the inner spacers. An anisotropic etch may be used to remove the dummy nanosheet in a straightforward way, with the remnants being shielded by the inner spacers. This makes it simple to create additional space beneath the remaining nanosheet channels.

A semiconductor device includes stacked nanosheet channels with inner spacers between respective pairs of the stacked nanosheet channels. Dummy nanosheet remnants are below respective inner spacers, vertically aligned with the respective inner spacers. A first source/drain structure is on first sidewalls of the plurality of stacked nanosheet channels. A second source/drain structure is on second sidewalls of the plurality of stacked nanosheet channels. A backside contact makes contact with the first source/drain structure. A frontside contact makes contact with the second source/drain structure. The removal of the dummy nanosheet, which leaves the dummy nanosheet remnants behind, provides additional space between the channels of the device and the backside contact to prevent shorting. The use of both frontside contacts and backside contacts simplifies the layout of interconnects to the device.

In embodiments, a first backside interlayer dielectric of a first dielectric material directly contacts the dummy nanosheet remnants. This first backside interlayer dielectric provides electrical insulation between the channels of the device and the backside contact.

In embodiments, a second backside interlayer dielectric of a second dielectric material, distinct from the first dielectric material, is around the backside contact. The use of two distinct backside interlayer dielectric materials helps to provide etch selectivity during a pre-silicide cleaning process, which helps to prevent shorts between the backside contacts and a gate stack.

In embodiments, the first backside interlayer dielectric comprises silicon carbide or silicon oxycarbide and the second backside interlayer dielectric comprises silicon oxide. These materials are selectively etchable, to protect the backside contacts and gate stack during pre-silicide cleaning.

In embodiments, a gate stack is around the stacked nanosheet channels and in direct contact with the first backside interlayer dielectric. This gate stack provides an electrical field to trigger the channel during operation of the device.

In embodiments, there is a frontside contact to the gate stack. The use of both frontside and backside contacts to the device helps to simplify interconnect layout.

In embodiments, a semiconductor placeholder structure is in the first backside interlayer dielectric. This remaining semiconductor placeholder is formed to improve critical dimension and etch uniformity, and need not be removed in the finished device.

In embodiments, a placeholder cap of a third dielectric material, distinct from the first dielectric material, is on the semiconductor placeholder structure. The placeholder cap may be left over from fabrication of the device, with remnant placeholders improving critical dimension and etch uniformity.

In embodiments, the dummy nanosheet remnants have a same width as the inner spacers. An anisotropic etch may be used to remove the dummy nanosheet in a straightforward way, with the remnants being shielded by the inner spacers. This makes it simple to create additional space beneath the remaining nanosheet channels.

A semiconductor device includes stacked nanosheet channels with inner spacers between respective pairs of the stacked nanosheet channels. Dummy nanosheet remnants are below respective inner spacers, vertically aligned with the respective inner spacers. A first source/drain structure is on first sidewalls of the plurality of stacked nanosheet channels. A second source/drain structure is on second sidewalls of the plurality of stacked nanosheet channels. A gate stack is around the stacked nanosheet channels. A first backside interlayer dielectric of a first dielectric material directly contacts the dummy nanosheet remnants and the gate stack. A backside contact makes contact with the first source/drain structure, through the first backside interlayer dielectric. A frontside contact makes contact with the second source/drain structure. The removal of the dummy nanosheet, which leaves the dummy nanosheet remnants behind, provides additional space between the channels of the device and the backside contact to prevent shorting. The use of both frontside contacts and backside contacts simplifies the layout of interconnects to the device.

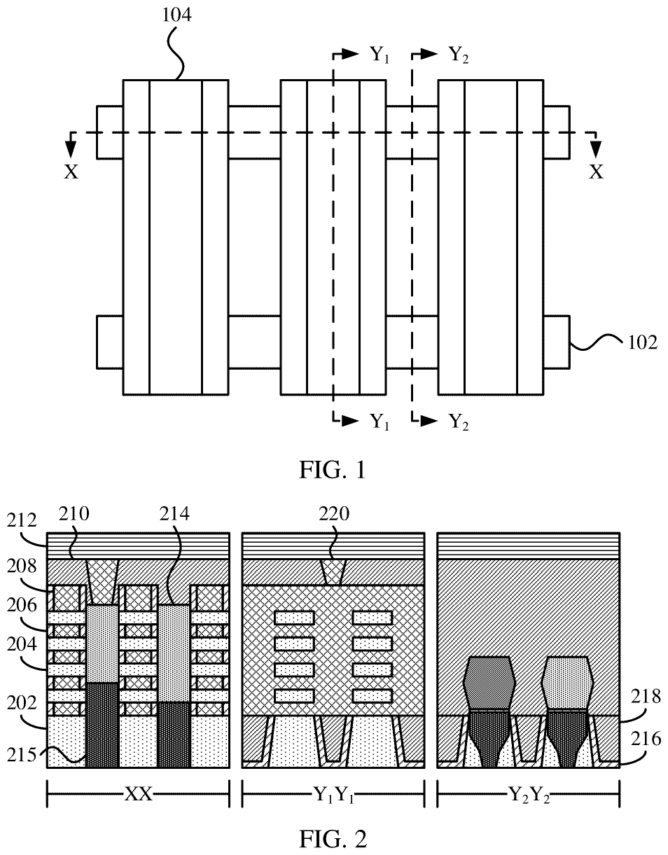

Referring now to FIG. 1, a top-down view of a semiconductor device is shown. The device includes a set of channels 102 with gates 104 across them. This view shows a set of cross-sectional cuts, including cross-section XX that cuts parallel to and through a channel 102, cross-section Y₁Y₁ that cuts perpendicular to the channel 102 and through a gate 104, and cross-section Y₂Y₂ that cuts perpendicular to the channel 102 and between gates 104, in a source/drain region. In some embodiments, the two depicted channels 102 may represent different device types, being formed from different respective materials and having different polarities (e.g., n-type and p-type).

Referring now to FIG. 2, a set of cross-sections is shown of a step in the fabrication of a semiconductor device. This step is shown after several steps in the fabrication of frontside device elements. Thus a set of semiconductor nanosheets 204 are formed over a semiconductor substrate 202 to act as nanosheet channels for the device. These semiconductor nanosheets 204 may be formed from a stack of alternating semiconductor materials, including a channel material and a selectively etchable sacrificial material, by successive epitaxial growth processes. Inner spacers 206 may be formed by recessing the sacrificial material, after which the sacrificial material may be etched away and may be replaced by a gate stack 208. The inner spacers 206 may therefore be positioned between respective pairs of semiconductor nanosheets 204.

Notably, there is no dielectric layer between the semiconductor nanosheets 204 and the semiconductor substrate 202, where there might otherwise be formed a self-aligned substrate isolation layer. Instead, a number of semiconductor nanosheets 204 are formed that exceed a number needed in a final design of the device. The bottommost semiconductor nanosheet 204 is a dummy nanosheet, and most of it will be removed in subsequent processing steps.

Source/drain structures 214 may be formed by epitaxial growth from exposed side surfaces of the semiconductor nanosheets 204. The source/drain structures 214 may be formed with in situ doping to create devices of differing polarities, for example with one device being formed with an n-type dopant and with another device being formed with a p-type dopant.

A frontside interlayer dielectric 210 is formed over the gate stacks 208 using any appropriate deposition process. Contacts 220 may be formed through the frontside interlayer dielectric 210 by etching a via using an anisotropic etch and depositing conductive material therein. One or more back-end-of-line (BEOL) layers 212 may then be formed over the frontside interlayer dielectric 210, for example by depositing a layer of dielectric material, forming trenches and vias in the dielectric material, and depositing conductive material in the trenches and vias. The BEOL layers 212 may thereby create interconnects between individual components of a semiconductor device, providing signal paths and power distribution to the device.

Processing may continue on the back side of the device, for example by adhering a carrier layer to the BEOL layers 212 and flipping the chip upside-down. Shallow trench isolation (STI) regions 218 are shown in the semiconductor substrate 202, having been formed by etching trenches into the semiconductor substrate 202 and filling those trenches with dielectric material. The STI regions 218 may have a dielectric liner 216 formed from a distinct dielectric material. During backside processing, substrate semiconductor material may be removed to expose the dielectric liner 216, leaving semiconductor substrate 202 in regions that are protected by the dielectric liner 216. Placeholder structures 215 may be formed in the semiconductor substrate 202, for example by epitaxial growth of a semiconductor material that is selectively etchable with respect to the material of the semiconductor substrate 202.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 202 may also be a semiconductor on insulator (SOI) substrate.

The semiconductor nanosheets 204 may similarly be formed from a silicon-containing material. As used herein, the terms “epitaxial growth” and/or “epitaxial deposition” means the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

Thus, the semiconductor nanosheets 204 may be formed by successive epitaxial growth processes, alternating between silicon and silicon germanium, with the latter forming sacrificial semiconductor layers. The germanium content of the silicon germanium may be selected to promote selective etching between the semiconductor nanosheets 204 and the sacrificial semiconductor layers.

To form the inner spacers 206, the sacrificial semiconductor layers may be partially recessed with respect to the semiconductor nanosheets 204 using a selective isotropic etch. The recesses may then be filled by conformal deposition of a dielectric material, such as silicon nitride, with any such material that is not protected within the recesses being removed by a subsequent selective anisotropic etch.

As used herein, the term “selective” in reference to a material removal process denotes that the rate of material removal for a first material is greater than the rate of removal for at least another material of the structure to which the material removal process is being applied. A selective anisotropic etch may include Reactive Ion Etching (RIE), which is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface.

The placeholder structures 215 may be formed prior to formation of the source/drain structures 214. For example, trenches may be formed in the semiconductor substrate 202 by a selective anisotropic etch between the semiconductor nanosheets 204, followed epitaxial growth of, e.g., silicon germanium from the exposed portion of the semiconductor substrate 202. The placeholder structures 215 may have different heights, with those heights being at any appropriate level between bottommost semiconductor nanosheet 204 and the inner spacers 206 above and below it.

The epitaxial growth of the source/drain structures 214 may be controlled to form such structures with different materials for different FETs. For example, one device region may be masked while the epitaxial growth is performed on the other. In one example, a first FET may be formed with phosphorus-doped silicon source/drain structures 214, while a second FET may be formed with boron-doped silicon germanium source/drain structures 214.

The gate stack 208 may be formed, after removing a dummy gate structure, by conformal deposition of a gate dielectric material, followed by deposition of a gate conductor. An optional work function metal layer may also be deposited before deposition of the gate conductor, to tune electrical properties of the FET such as the threshold voltage.

The gate dielectric may be formed from, e.g., a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

The gate conductor may be formed from any appropriate conductive material, such as, e.g., tungsten, nickel, titanium, molybdenum, tantalum, copper, platinum, silver, gold, ruthenium, iridium, rhenium, rhodium, cobalt, and alloys thereof. The gate conductor may alternatively be formed from a doped semiconductor material such as, e.g., doped polysilicon.

Deposition processes described herein may be, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25°C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

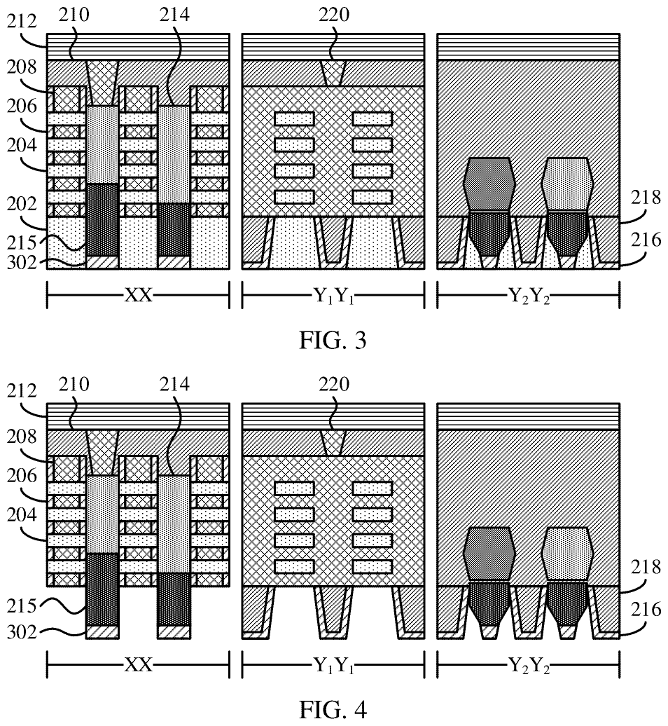

Referring now to FIG. 3, a set of cross-sections is shown of a step in the fabrication of a semiconductor device. The placeholder structures 215 are selectively etched back and a dielectric material is conformally deposited to fill the resulting recesses, creating dielectric caps 302 from, e.g., silicon nitride. Any excess dielectric material may be removed by, e.g., a chemical mechanical planarization (CMP) process.

CMP is performed using, e.g., a chemical or granular slurry and mechanical force to gradually remove upper layers of the device. The slurry may be formulated to be unable to dissolve, for example, the semiconductor material of the semiconductor substrate 202, resulting in the CMP process's inability to proceed any farther than that layer.

Referring now to FIG. 4, a set of cross-sections is shown of a step in the fabrication of a semiconductor device. The remaining portions of the semiconductor substrate 202 are selectively etched away, exposing side surfaces of the placeholder structures 215.

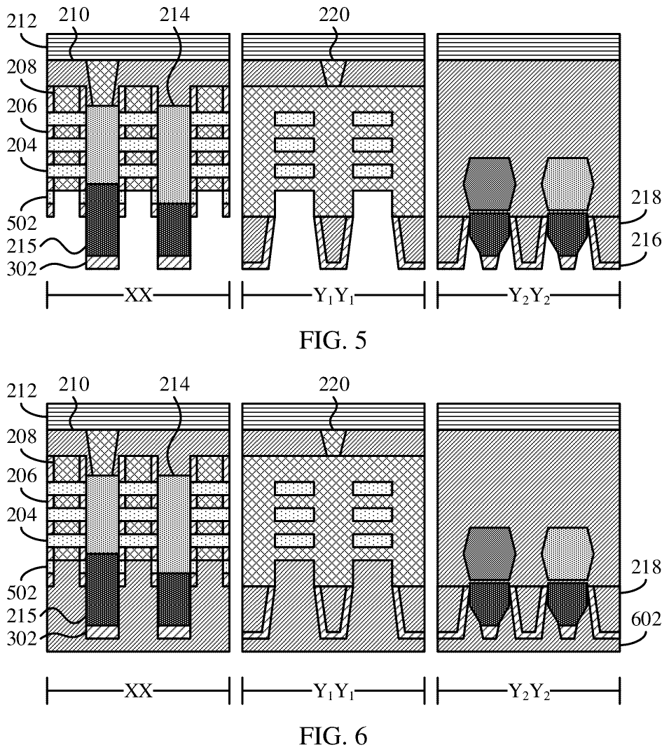

Referring now to FIG. 5, a set of cross-sections is shown of a step in the fabrication of a semiconductor device. An anisotropic etch is used to remove exposed portions of the gate stack 208 and the bottommost semiconductor nanosheet 204. The etch is selective and does not damage the material of the dielectric caps 302 or the inner spacers 206. The etch is blocked by the inner spacers 206, which protect end portions of the bottommost semiconductor nanosheet 204, leaving behind dummy nanosheet remnants 502. The dummy nanosheet remnants 502 may be positioned between and vertically aligned with inner spacers 206 and may have approximately the same width as the inner spacers 206.

Referring now to FIG. 6, a set of a set of cross-sections is shown of a step in an embodiment of the fabrication of a semiconductor device. In some embodiments, a single backside interlayer dielectric 602 may be deposited to cover the placeholder structures 215 and the dielectric caps 302, filling in the recessed area under the semiconductor nanosheets 204. This backside interlayer dielectric 602 may be formed from silicon dioxide, for example using a flowable CVD process.

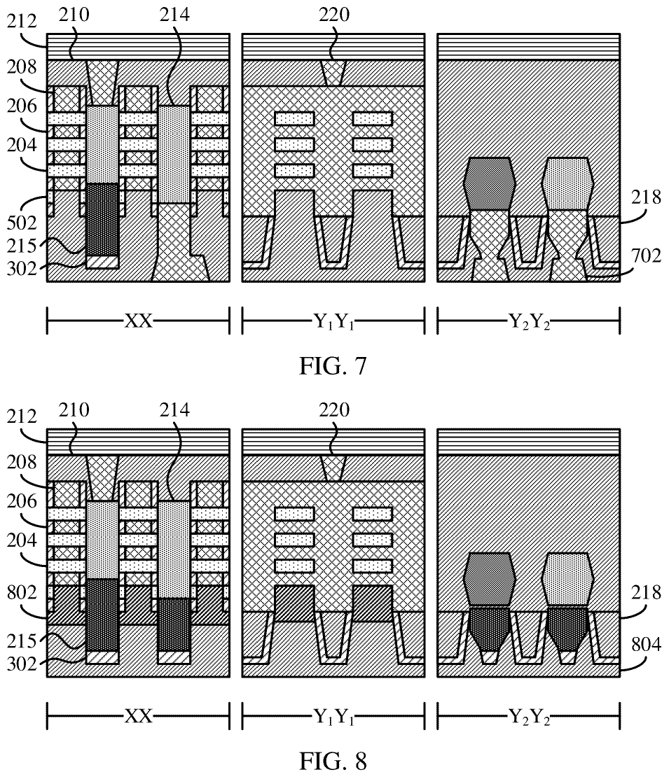

Referring now to FIG. 7, a set of a set of cross-sections is shown of a step in an embodiment of the fabrication of a semiconductor device. In some embodiments, vias may be etched through the backside interlayer dielectric 602 to expose one or more of the dielectric caps 302. The dielectric cap may then be selectively etched away to expose the corresponding placeholder structures 215. Exposed placeholder structures 215 may be selectively etched away and may be replaced by deposition of conductive material, thereby forming backside contacts 702. Any excess conductive material may be removed using a CMP process that stops on the backside interlayer dielectric 602. Backside interconnects may be formed at this stage, for example including backside power distribution and/or signal interconnects that interface with the backside contacts 702. Notably, a placeholder structure 215 may remain buried in the backside interlayer dielectric 602. Such dummy placeholders may be formed to improve critical dimension and etch uniformity.

Referring now to FIG. 8, a set of a set of cross-sections is shown of a step in an alternative embodiment of the fabrication of a semiconductor device. In some embodiments, a two-layer backside interlayer dielectric may be formed, including a first layer 802 and a second layer 804. The two interlayer dielectrics may include different respective dielectric materials. For example, the first layer 802 may be formed from silicon carbide or silicon oxycarbide, while the second layer 804 may be formed from silicon oxide.

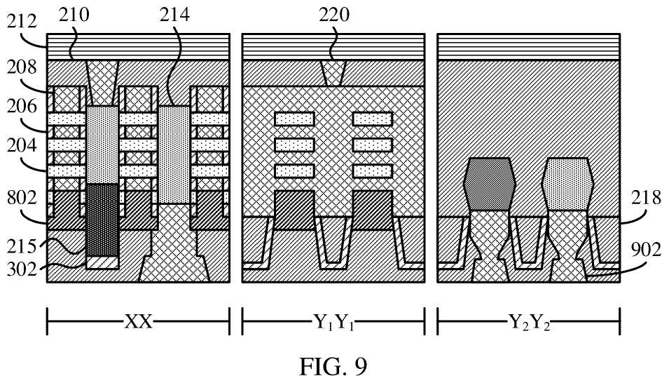

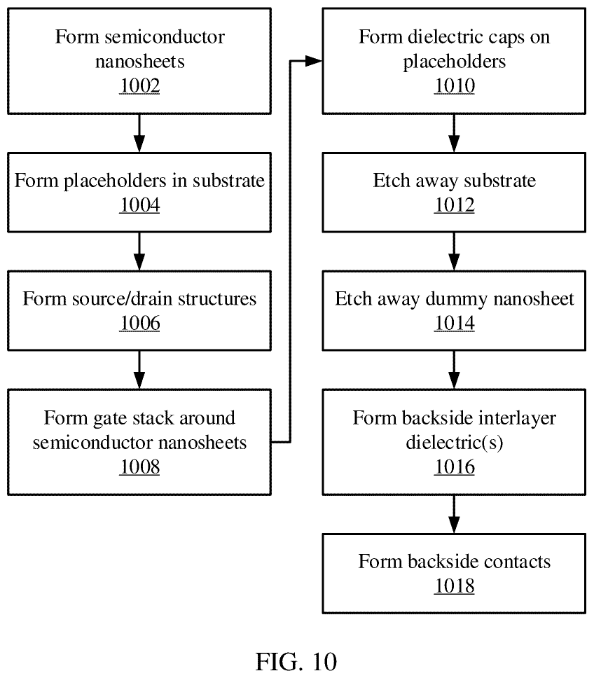

Referring now to FIG. 9, a set of a set of cross-sections is shown of a step in an alternative embodiment of the fabrication of a semiconductor device. As above, vias may be etched through the backside interlayer dielectric 602 to expose one or more of the dielectric caps 302. The dielectric cap may then be selectively etched away to expose the corresponding placeholder structures 215.

Exposed placeholder structures 215 may be selectively etched away and may be replaced by deposition of conductive material, thereby forming backside contacts 902. The first backside interlayer dielectric layer 802 provides etch selectivity during a pre-silicide cleaning process, which helps to prevent shorts between the backside contacts 902 and the gate stack 208. Backside interconnects may be formed at this stage, for example including backside power distribution and/or signal interconnects that interface with the backside contacts 902.

Referring now to FIG. 10, a method of fabricating a semiconductor device is shown. Block 1002 forms semiconductor nanosheets 204, including at least one nanosheet that will remain as a channel in the final device and a dummy nanosheet. These nanosheets may be formed by, e.g., epitaxial growth of successive layers of channel material and sacrificial material. The sacrificial material may be selectively etched away to leave the semiconductor nanosheets 204 suspended.

Block 1004 forms placeholder structures 215 within the semiconductor substrate 202, for example by an anisotropic etch followed by a deposition of a material with appropriate etch selectivity. Block 1006 grows source/drain structures 214 from exposed side surfaces of the semiconductor nanosheets 204, for example using an epitaxial growth process with in situ doping. Block 1008 forms a gate stack 208 around the semiconductor nanosheets 204, for example using a conformal deposition of a high-k gate dielectric and one or more conductive materials (e.g., including a work function metal layer and/or a gate conductor).

Block 1010 forms dielectric caps 302 on the placeholder structures 215, for example by etching the placeholder structures 215 back from the backside of the device, depositing a dielectric material, and polishing away excess dielectric material using a CMP process. Block 1012 then etches away remaining portions of the semiconductor substrate 202, exposing sidewalls of the placeholder structures 215. Block 1014 performs a further selective etch that removes exposed material from the gate stack 208 and the bottommost semiconductor nanosheet 204, leaving edges of this dummy nanosheet in sidewalls between the inner spacers 206.

Block 1016 then forms backside interlayer dielectric(s). This may be a single-layer backside interlayer dielectric 602 or may instead include a first layer 802 and a second layer 804 formed from distinct dielectric materials. Block 1018 forms backside contacts 902 by removing the placeholder structures 215 and replacing them with conductive material.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled”to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of FETs with dummy nanosheets (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a plurality of stacked nanosheet channels;
inner spacers between respective pairs of the plurality of stacked nanosheet channels;
dummy nanosheet remnants below respective inner spacers, vertically aligned with the respective inner spacers;
a source/drain structure on sidewalls of the plurality of stacked nanosheet channels; and
a backside contact to the source/drain structure.

2. The semiconductor device of claim 1, further comprising a first backside interlayer dielectric of a first dielectric material that directly contacts the dummy nanosheet remnants.

3. The semiconductor device of claim 2, further comprising a second backside interlayer dielectric of a second dielectric material, distinct from the first dielectric material, around the backside contact.

4. The semiconductor device of claim 3, wherein the first backside interlayer dielectric comprises silicon carbide or silicon oxycarbide and the second backside interlayer dielectric comprises silicon oxide.

5. The semiconductor device of claim 2, further comprising a gate stack around the plurality of stacked nanosheet channels and in direct contact with the first backside interlayer dielectric.

6. The semiconductor device of claim 5, further comprising a frontside contact to the gate stack.

7. The semiconductor device of claim 2, further comprising a semiconductor placeholder structure in the first backside interlayer dielectric.

8. The semiconductor device of claim 7, further comprising a placeholder cap of a third dielectric material, distinct from the first dielectric material, on the semiconductor placeholder structure.

9. The semiconductor device of claim 1, wherein the dummy nanosheet remnants are formed from a same semiconductor material as the plurality of stacked nanosheet channels.

10. The semiconductor device of claim 1, wherein the dummy nanosheet remnants have a same width as the inner spacers.

11. A semiconductor device, comprising:
a plurality of stacked nanosheet channels;
inner spacers between respective pairs of the plurality of stacked nanosheet channels;
dummy nanosheet remnants below respective inner spacers, vertically aligned with the respective inner spacers;
a first source/drain structure on first sidewalls of the plurality of stacked nanosheet channels;
a second source/drain structure on second sidewalls of the plurality of stacked nanosheet channels;
a backside contact to the first source/drain structure; and
a frontside contact to the second source/drain structure.

12. The semiconductor device of claim 11, further comprising a first backside interlayer dielectric of a first dielectric material that directly contacts the dummy nanosheet remnants.

13. The semiconductor device of claim 12, further comprising a second backside interlayer dielectric of a second dielectric material, distinct from the first dielectric material, around the backside contact.

14. The semiconductor device of claim 13, wherein the first backside interlayer dielectric comprises silicon carbide or silicon oxycarbide and the second backside interlayer dielectric comprises silicon oxide.

15. The semiconductor device of claim 12, further comprising a gate stack around the plurality of stacked nanosheet channels and in direct contact with the first backside interlayer dielectric.

16. The semiconductor device of claim 15, further comprising a frontside contact to the gate stack.

17. The semiconductor device of claim 12, further comprising a semiconductor placeholder structure in the first backside interlayer dielectric.

18. The semiconductor device of claim 17, further comprising a placeholder cap of a third dielectric material, distinct from the first dielectric material, on the semiconductor placeholder structure.

19. The semiconductor device of claim 11, wherein the dummy nanosheet remnants have a same width as the inner spacers.

20. A semiconductor device, comprising:
a plurality of stacked nanosheet channels;
inner spacers between respective pairs of the plurality of stacked nanosheet channels;
dummy nanosheet remnants below respective inner spacers, vertically aligned with the respective inner spacers;
a first source/drain structure on first sidewalls of the plurality of stacked nanosheet channels;
a second source/drain structure on second sidewalls of the plurality of stacked nanosheet channels;
a gate stack around the plurality of stacked nanosheet channels;
a first backside interlayer dielectric of a first dielectric material that directly contacts the dummy nanosheet remnants and the gate stack;
a backside contact to the first source/drain structure, through the first backside interlayer dielectric; and
a frontside contact to the second source/drain structure.
